(19) United States
(12) Patent Application Publication
(10) Pub. No.: US 2008/0054310 A1
(43) Pub. Date: Mar. 6, 2008

(54) Capacitorless DRAM memory cell comprising a partially-depleted MOSFET device comprising a gate insulator in two parts

(75) Inventor: Georges Guegan, Seyssins (FR)

Correspondence Address: OLIFF & BERRIDGE, PLC, P.O. BOX 320850, ALEXANDRIA, VA, 22320-4850, US

(73) Assignee: COMMISSARIAT A L'ENERGIE ATOMIQUE, PARIS (FR)

(21) Appl. No.: 11/889,739

(22) Filed: Aug. 16, 2007

(30) Foreign Application Priority Data
Sep. 1, 2006 (FR) 06/07691
May 15, 2007 (FR) 07/03486

(51) Int. Cl. H01L 29/78; G11C 11/34

(52) U.S. Cl. 257/214; 365/185.26; 257/E29.227

(57) ABSTRACT

The capacitorless DRAM memory cell is constituted by a partially-depleted MOSFET device successively comprising a base substrate, a buried insulator, a floating substrate from semiconducting material including a channel, the gate insulator and a gate. The gate comprises a first zone doped by a first type of dopant and a second zone doped by a second type of dopant. The channel is doped by the second type of dopant. The gate insulator comprises a first part corresponding to the first doped zone and a second part corresponding to the second doped zone of the gate. The first part of the gate insulator has a higher tunnel resistance than the second part. Data storage is realized by means of charge carrier transportation from the gate to the floating substrate through the lower tunnel resistance part of the gate insulator.

### BACKGROUND OF THE INVENTION

The invention relates to a capacitor-less DRAM memory cell constituted by a partially-depleted MOSFET device successively comprising a base substrate, a buried insulator, a floating substrate made from semiconducting material including a channel, at least one gate insulator and a gate, the gate comprising a first zone doped by a first type of dopant and at least a second zone doped by a second type of dopant, the semiconducting material channel being doped by the second type of dopant.

### STATE OF THE ART

SOI (Silicon On Insulator) technologies present numerous advantages, for example:
good irradiation resistance,
good dielectric insulation of the transistors and circuits as well as an absence of latch-up effects, i.e. current fluxes between the PMOS and NMOS transistors of a CMOS circuit,
reduction of short-channel effects,
reduction of stray capacitances of the junctions, leading to faster operation of the circuits and a reduction of the powers consumed.

SOI devices can be divided into two major families: fully depleted devices and partially-depleted devices. In partially-depleted devices controlled by a gate, the space charge zone does not reach the buried insulator.

However, in general manner, partially-depleted devices are limited by floating body effects, in particular for analog applications.

Device performances in terms of delivered currents, gain in mobility and circuit consumption reduction are moreover sought to be improved. Floating substrate effects result in an increased saturation current (kink effect) which is very penalizing for analog applications.

Nevertheless, PD SOI MOSFET device can constitute a capacitor-less DRAM memory cell (or “1T DRAM”) thanks to floating body effect. In this kind of memory cell, data storage within the device is performed by means of the floating substrate effect of the MOS transistors achieved with a partially-depleted SOI technology.

Conventionally, this type of capacitor-less memory cell, is achieved by means of NMOS transistors. In this type of memory cell, charge carriers (holes for an NMOS transistor) are injected into the neutral zone of the floating substrate. These carriers, confined in a region bounded by the buried oxide, the gate oxide and the source and drain junctions, accumulate in the floating substrate and modify its potential. This potential increases in the case of an NMOS transistor, directly connecting the source/floating substrate junction. The threshold voltage of the transistor is thus reduced and the drain current increases. In this case, the floating substrate is used as a memory charge storage zone. This stored charge (1 state of the memory) can be evacuated by forward biasing of the drain/substrate junction. The 0 state of the memory corresponds to the absence of charge in the floating substrate.

In this memory cell, creation of charge carrier is realized thanks to collision ionisation, which allows the accumulation of a large amount of electrons. However, in general manner, charge carrier are injected in these memory cells with by means of high electric field which is prejudicial to the reliability of the device.

The document US2005/0072975 describes a partially-depleted MOSFET device formed from a SOI (Silicon on Insulator) substrate successively comprising a base substrate, a buried insulator, a channel made from semiconducting material, a gate insulator and a gate. The gate comprises a first zone doped by a first type of dopant and at least a second zone doped by a second type of dopant. The semiconducting material channel is doped by the second type of dopant. The source and drain are doped by the first type of dopant.

A tunnel effect connection is thus formed between the second doped zone and the transistor channel, if the thickness of the gate insulator is small, for example comprised between 1 nm and 2.2 nm. This enables the charge and the potential of the semiconducting layer in which the channel is formed to be modified, thus enabling the absolute value of the threshold voltage of the MOSFET device to be reduced. This threshold voltage reduction results in an increase of the delivered current. In addition, the weakly reversed slope, which expresses the switching capacity of a transistor from the off state to the on state, is improved due to a smaller variation of the depletion capacity with the bias applied to the gate. Reduction of the absolute value of the threshold voltage results in a reduction of the electric field in saturation conditions near the drain and a reduction of collision ionization.

Moreover, implementation of a tunnel current between the gate and channel enables an increased conductivity in the on state, a reduction of collision ionization and of the kink effect, a gain in mobility and a reduction of short-channel effects to be achieved.

These advantages are on the other hand reduced in the case of use of high voltages, in particular for analog applications.

### OBJECT OF THE INVENTION

The object of the invention consists in providing a capacitorless DRAM memory cell presenting the advantages of being suitable for high reliability requirement.

According to the invention, this object is achieved by the capacitorless DRAM memory cell according to the appended claims.

### BRIEF DESCRIPTION OF THE DRAWINGS

Other advantages and features will become more clearly apparent from the following description of particular embodiments of the invention given as non-restrictive examples only and represented in the accompanying drawings, in which:

FIGS. 1 to 4 respectively represent a particular embodiment of a memory cell according to the invention, in top view and in cross-section along the lines A-A, B-B and C-C,

FIG. 5 represents another particular embodiment of a memory cell according to the invention in cross-section along the line A-A.

### DESCRIPTION OF A PREFERRED EMBODIMENT OF THE INVENTION

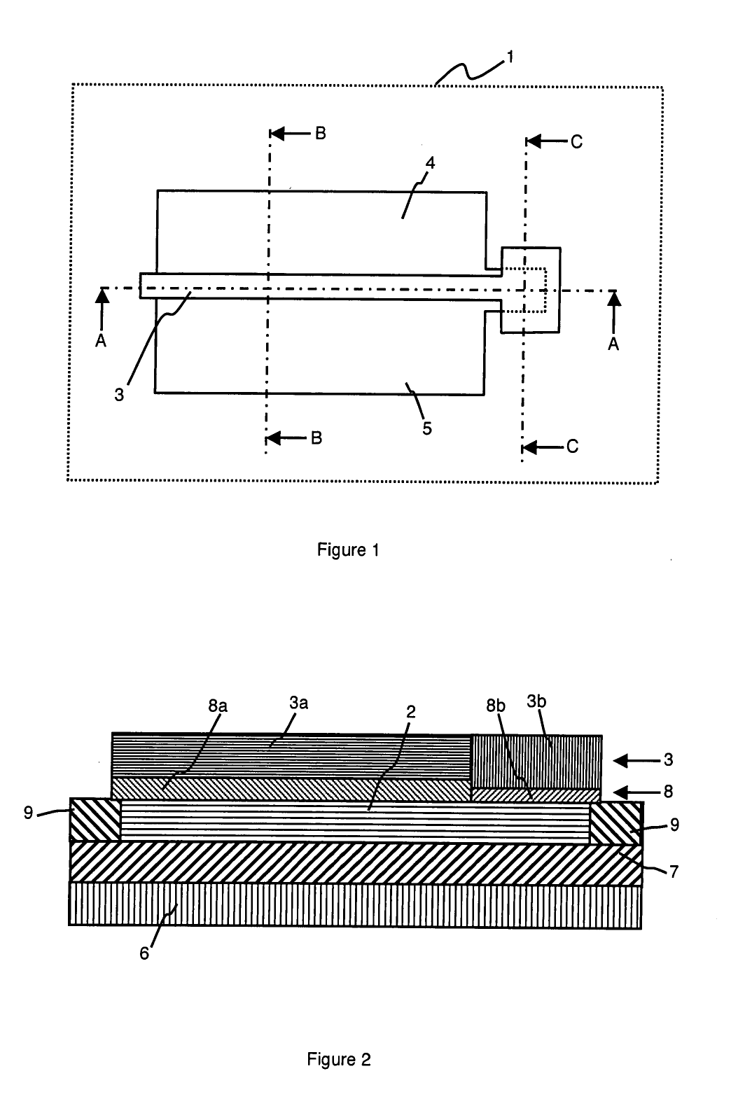

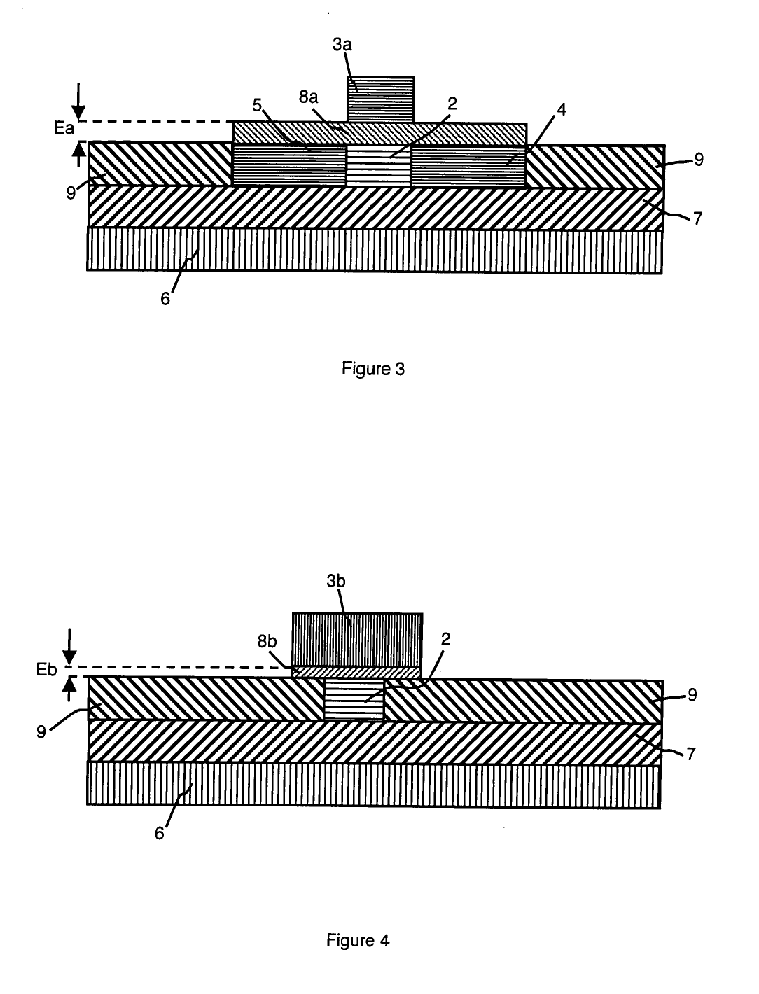

The capacitor-less DRAM memory cell comprises a partially-depleted MOSFET device 1 represented in FIGS. 1 to 4, which comprises a substrate at floating potential, called floating substrate, made of semiconducting material and comprising a channel 2 at the top part thereof (see FIG. 2) arranged under a gate 3. Source and drain electrodes 4 and 5 are formed on each side of the channel 2.

As represented in FIG. 2, the device successively comprises a base substrate 6, a buried insulator 7, the floating substrate made of semiconducting material comprising the channel 2, at least one gate insulator 8 and the gate 3. The gate 3 is for example made from polysilicon. The gate 3 comprises a first doped zone 3a doped by a first type of dopant (for example P+) and a second doped zone 3b doped by a second opposite type of dopant (for example N+). The semiconducting material channel 2 is doped by the second type of dopant. Thus, the second doped zone 3b is doped by the same type of dopant as the channel 2. A tunnel effect connection is thus formed between the second doped zone 3b and the channel 2. In the example, the first type of dopant is P+ and the second type of dopant is N+. In another example, the first type of dopant can be N and the second type of dopant is therefore P.

The source and drain electrodes 4 and 5 are doped by the first type of dopant. The source and drain electrodes 4 and 5 and the channel 2 are for example formed in an active layer laterally delimited by insulating elements 9.

The gate insulator 8 comprises a first part 8a corresponding to the first doped zone 3a and a second part 8b corresponding to the second doped zone 3b of the gate 3.

In the particular embodiment represented in FIGS. 2 to 4, the first part 8a of the gate insulator 8 has a larger thickness Ea than the thickness Eb of the second part 8b of the gate insulator 8. In this way, even when the materials of the first (8a) and second (8b) parts are the same, the first part 8a of the gate insulator 8 has a higher tunnel resistance than the second part 8b of the gate insulator 8.

For example, the first part 8a of the gate insulator 8 has a thickness Ea comprised between 1.2 nm and 7 nm, and preferably between 2 nm and 5 nm, and the second part 8b of the gate insulator 8 has a thickness Eb comprised between 1 nm and 2.2 nm.

The first and second parts 8a and 8b of the gate insulator 8 can for example be formed by the same material, for example by a material comprised in the group containing silicon oxide SiO₂, carbonaceous silicon oxides SiOC, hydrocarbonaceous silicon oxides SiOCH and nitrided silicon oxide SiON or hafnium oxide HfON.

The first part 8a of the gate insulator 8 therefore has a higher tunnel resistance than the second part 8b of the gate insulator 8. Due to the larger thickness Ea of the first zone 8a of the gate insulator 8, higher voltages can be used, in particular for analog applications, without causing tunnel currents through the first part 8a of the gate insulator, whereas the tunnel junction corresponding to the second doped zone 3b of the gate 3 is adjusted by the thickness Eb of the second part 8b of the gate insulator 8 to enhance the tunnel current, independently from the first part 8a.

The direct tunnel effect between the second doped zone 3b of the gate 3 and the channel 2 is enhanced by the reduction of the thickness Eb of the second part 8b of the gate insulator 8 or by the choice of a dielectric with a weaker dielectric constant or a smaller barrier height for the second part 8b of the gate insulator 8 than the dielectric of the first part 8a of the gate insulator 8.

In prior art devices, if the supply voltage is high, the thickness of the dielectric has to be increased for the latter not to be damaged, but there is then no longer any conduction by tunnel effect as the dielectric is too thick.

The first part 8a of the gate insulator 8 can have a higher dielectric constant than the second part 8b of the gate insulator 8. The first part 8a of the gate insulator 8 can for example be made of a material with a high dielectric constant (high K type), for example a material comprised in the group containing hafnium oxide HfO₂, hafnium silicates HfSiOₓ (x being comprised between 1 and 3) and nitrided silicon oxide SiON. The second part 8b of the gate insulator 8 can for example be made of a material comprised in the group containing silicon oxide SiO₂, carbonaceous silicon oxides SiOC and hydrocarbonaceous silicon oxides SiOCH.

In a preferred embodiment, the first part 8a of the gate insulator 8 is made of SiO₂ and has a thickness comprised between 2 nm and 3 nm, and the second part 8b of the gate insulator 8 is also made of SiO₂ and has a thickness comprised between 1 nm and 1.5 nm.

In another embodiment, the first part 8a of the gate insulator 8 is made of a high dielectric constant material and has a thickness comprised between 2 nm and 6 nm and preferably 2.5 nm, and the second part 8b of the gate insulator 8 is made of SiO₂ and has a thickness comprised between 1 nm and 2.2 nm and preferably 1.5 nm.

Depending on the supply voltages used, different choices can be envisaged for the materials and their thicknesses. For a supply voltage of the circuits of 1V, the first part 8a of the gate insulator 8 can for example be made of HfO₂ with a thickness of 3 nm, and the second part 8b of the gate insulator 8 can be made of SiO₂ with a thickness of 1.9 nm.

For a supply voltage of the circuits of 1.2V, the first part 8a of the gate insulator 8 can for example be made of SiON with a thickness of 2.7 nm, and the second part 8b of the gate insulator 8 can be made of SiO₂ with a thickness of 1.9 nm.

For a supply voltage of the circuits of 2.5V, the first part 8a of the gate insulator 8 can for example be made of SiO₂ with a thickness of 5 nm, and the second part 8b of the gate insulator 8 can be made of SiO₂ with a thickness of 2.2 nm. The SiO₂ can contain a small quantity of nitrogen (a few %) in order to increase the quality of the dielectric.

The thicknesses Ea and Eb and/or the materials of the first (8a) and second (8b) part of the gate insulator 8 can for example be determined by means of simulations or theoretical calculations, known to the person skilled in the art. Theoretical calculations can for example be made from direct tunnel effect or Fowler-Nordheim tunnel effect conduction models. It is also possible to determine the thicknesses Ea and Eb and/or the materials of the first (8a) and second (8b) part of the gate insulator 8 by means of experimental tests based on assemblies of capacitor or transistor type by measuring current-voltage or capacitance-voltage characteristics. For example, a leakage current density of 800 pA/μm² is sufficient under a voltage of 1V to regulate the channel potential from a tunnel current through a nitrided silicon oxide with a thickness of 1.9 nm arranged between an N type monocrystalline silicon layer and N+ type polysilicon. This tunnel current is generated by the electrons accumulated in the N+ type polysilicon passing into the N type monocrystalline silicon layer.

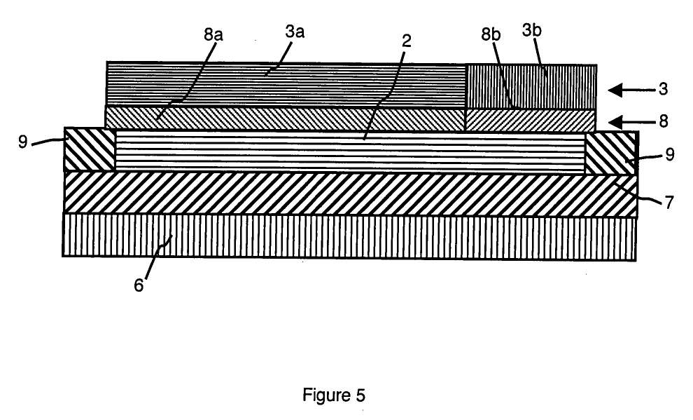

In the particular embodiment represented in FIG. 5, the thicknesses Ea and Eb are equal. In this case, the materials of the first (8a) and second (8b) parts are different. The material of the first part 8a of the gate insulator 8 can for example present a larger barrier height than the material of the second part 8b of the gate insulator 8. When the thicknesses of the first and second parts are equal, the material of the first part 8a of the gate insulator 8 preferably has a lower dielectric constant than the material of the second part 8b of the gate insulator 8.

For example, the first part 8a can be made from silicon oxide SiO₂ and the second part 8b can be made from an oxide with a high dielectric constant, for example HfO₂, the two parts 8a and 8b having the same thickness, for example 2 nm. The conduction by direct tunnel effect of the second part 8b is in this case several decades greater than that of the first part 8a. The first part 8a of the gate insulator 8 therefore has a higher tunnel resistance than the second part 8b of the gate insulator 8.

The common element of the different embodiments is the fact that the first part 8a and the second part 8b of the gate insulator 8 are distinct. They are in fact differentiated in particular by their thickness and/or by their material. The device according to the invention can be fabricated by means of the techniques usually used in microelectronics, such as resist depositions, lithographies and ion implantations.

Such a device is partially known from the document U.S. Pat. No. 6,693,328 which describes the use of the gate in order to introduce an electron leakage tunnel current to the channel. This document does not discloses or suggest the use of a MOSFET device as a memory cell.

The MOSFET device according to the invention constitutes a capacitor-less DRAM memory cell (or “1T DRAM”). In this memory cell, data storage within the device is performed by means of the floating substrate effect of the MOS transistors achieved with a partially-depleted SOI technology.

Conventionally, this type of capacitor-less memory cell, is preferably achieved by means of NMOS transistors. In this type of memory cell, charge carriers (holes for an NMOS transistor) are injected into the neutral zone of the floating substrate. These carriers, confined in a region bounded by the buried oxide, the gate oxide and the source and drain junctions, accumulate in the floating substrate and modify its potential. This potential increases in the case of an NMOS transistor, directly connecting the source/floating substrate junction. The threshold voltage of the transistor is thus reduced and the drain current increases. In this case, the floating substrate is used as a memory charge storage zone. This stored charge (1 state of the memory) can be evacuated by forward biasing of the drain/substrate junction. The 0 state of the memory corresponds to the absence of charge in the floating substrate.

Unlike capacitor-less memory cells of known type where charge creation in the floating substrate is performed by collision ionization (“A SOI capacitor-less 1T-DRAM Concept”, S. Okhonin et al. Proc. of the IEEE International SOI Conf, p. 153, 2001) thus favoring the use of NMOS transistors, the use of a transistor comprising a zone having a lower tunnel resistance easily allows charges to be introduced into the floating substrate by this zone. With the device according to the invention on the other hand, it is preferable to use a PMOS device.

The read phase is typically performed by turning the transistor to the On state, i.e. for example, for a PMOS device, by applying a potential of about −0.1V to the drain and a potential of about −0.6V to the gate, the source being arbitrarily fixed at 0. The potential difference existing between the gate and source is lower than the threshold potential difference above which a sufficient direct tunnel current is created to introduce charges into the floating substrate. This threshold potential difference is linked to the tunnel resistance of the gate insulator 8 and translates the potential difference for which the direct tunnel current presents an important effect on the characteristics of the device. In general manner, the sign of the potential differences between the transistor electrodes and the precise amplitudes of these differences depend on the type of device (NMOS or PMOS) and on the technological node used.

Write of a “1” is performed by introducing charges, here electrons, originating from the second doped zone 3b of the gate 3 into the floating substrate through the second part of the gate insulator 8b. The second doped zone 3b is preferably used as it presents a lower tunnel resistance than the first doped zone. This write phase of a “1” is performed for example by applying a potential of about −1V to the gate, and of −0.1V to the drain, the source being arbitrarily fixed at 0, i.e. by applying a voltage Vgs of −1V between the gate and source and a voltage Vds of −0.1V between the drain and source. In schematic manner, the potential conditions taken are as for a read, but the amplitude of the potential difference between the source and gate is increased, for example by about 50%, or by applying a potential difference about 10 times greater between the gate and drain than between the source and drain which is also equivalent in this configuration by applying a potential difference about 10 times greater between the gate and source than between the source and drain. This increase of the potential difference enables a potential difference to be obtained between the gate and source that is greater than the threshold potential difference, thereby enabling a sufficient direct tunnel current to be created, from the gate 3, to induce charges in the floating substrate.

Moreover, for a PMOS device, write of a “0” is performed for example by fixing the source and gate at the same potential, for example 0, and fixing the drain at 0.1V. In general manner, write of a “0” is performed by applying a potential difference of the same amplitude between the source and drain but of opposite sign to that of read or write of a “1”. The drain/floating substrate junction is therefore forward biased. The charges stored in the floating substrate are therefore evacuated.

The retention phase is performed in conventional manner without applying a potential difference between the different electrodes.

We claim:

1. A capacitor-less DRAM memory cell constituted by a partially-depleted MOSFET device successively comprising a base substrate, a buried insulator, a floating substrate made from semiconducting material including a channel, at least one gate insulator and a gate, the gate comprising a first zone doped by a first type of dopant and at least a second zone doped by a second type of dopant, the semiconducting material channel being doped by the second type of dopant, a device wherein the gate insulator comprises a first part corresponding to the first doped zone and a second part corresponding to the second doped zone of the gate, the first part of the gate insulator having a higher tunnel resistance than the second part of the gate insulator.

2. The memory cell according to claim 1, wherein the first part of the gate insulator and the second part of the gate insulator have equal thicknesses, the materials of the first and second parts of the gate insulator being different.

3. The memory cell according to claim 2, wherein the first part of the gate insulator has a lower dielectric constant than the second part of the gate insulator.

4. The memory cell according to claim 3, wherein the first part of the gate insulator is made of silicon oxide and the second part of hafnium oxide.

5. The memory cell according to claim 1, wherein the first part of the gate insulator has a larger thickness than the second part of the gate insulator.

6. The memory cell according to claim 5, wherein the first part of the gate insulator has a thickness comprised between 1.2 nm and 7 nm and the second part of the gate insulator has a thickness comprised between 1 nm and 2.2 nm.

7. The memory cell according to claim 6, wherein the first part of the gate insulator has a thickness comprised between 2 nm and 5 nm.

8. The memory cell according to claim 5, wherein the first and second parts of the gate insulator are formed by the same material.

9. The memory cell according to claim 8, wherein the first and second parts of the gate insulator are made of a material comprised in the group containing silicon oxide, carbonaceous silicon oxides and hydrocarbonaceous silicon oxides.

10. The memory cell according to claim 5, wherein the first part of the gate insulator has a higher dielectric constant than the second part of the gate insulator.

11. The memory cell according to claim 10, wherein the first part of the gate insulator is made of a material with a high dielectric constant.

12. The memory cell according to claim 11, wherein the first part of the gate insulator is made of a material comprised in the group containing hafnium oxide, hafnium silicates and nitrided silicon oxide.

13. The memory cell according to claim 10, wherein the second part of the gate insulator is made of a material comprised in the group containing silicon oxide, carbonaceous silicon oxides, hydrocarbonaceous silicon oxides and nitrided silicon and hafnium oxides.

14. A method for using the DRAM memory cell according to claim 1, wherein injection of charge carriers to write a 1 state is performed by simultaneous application of a potential difference between the gate and the source that is greater than the characteristic threshold potential difference of the tunnel current through the second part of the gate insulator, and of a potential difference between the source and drain that is typical of an On state of the device.

15. The method according to claim 14, wherein when writing of a 1 state is performed, the potential difference between the gate and source is about ten times the potential difference between the drain and source.

16. The method according to claim 14, wherein writing of a 1 state is performed by simultaneous application of a drain-source voltage of about −0.1V and of a gate-source voltage of about −1V.

17. The method according to claim 14, wherein writing of a 0 state is performed by simultaneous application of a substantially zero potential difference between the gate and source and of a potential difference between the drain and source opposite to that of writing of a 1 state.

18. The method according to claim 17, wherein when reading is performed, the potential difference between the source and drain is about a few tens of millivolts.
